(19) United States
(12) Patent Application Publication
(10) Pub. No.: US 2015/0060956 A1
(43) Pub. Date: Mar. 5, 2015

(54) INTEGRATED MEMS PRESSURE SENSOR WITH MECHANICAL ELECTRICAL ISOLATION

(71) Applicant: WindTop Technology Corp., Hsinchu City (TW)

(72) Inventor: Kun-Lung Chen, Hsinchu City (TW)

(73) Assignee: WindTop Technology Corp., Hsinchu City (TW)

(21) Appl. No.: 14/016,311

(22) Filed: Sep. 3, 2013

(51) Int. Cl. B81B 7/00; B81B 3/00; B81C 1/00

(52) U.S. Cl. CPC B81B 7/0006; B81C 1/00134; B81B 3/0021
USPC 257/254; 438/50

(57) ABSTRACT

An integrated MEMS pressure sensor is provided, including, a CMOS substrate layer, an N+ implant doped silicon layer, a field oxide (FOX) layer, a plurality of implant doped silicon areas forming CMOS wells, a two-tier polysilicon layer with selective ion implantation forming a membrane, including an implant doped polysilicon layer and a non-doped polysilicon layer, a second non-doped polysilicon layer, a plurality of implant doped silicon areas forming CMOS source/drain, a gate poly layer made of polysilicon forming CMOS transistor gates, said CMOS wells, CMOS transistor sources/drains and CMOS gates forming CMOS transistors, an oxide layer embedded with an interconnect contact layer, a plurality of metal layers interleaved with a plurality of via hole layers, a Nitride deposition layer, an under bump metal (UBM) layer and a plurality of solder spheres. N+ implant doped silicon layer and implant doped/un-doped composition polysilicon layer forming a sealed vacuum chamber.

### FIELD OF THE INVENTION

The present invention generally relates to an integrated MEMS device, and more specifically to an integrated MEMS device built with CMOS process, Flip Chip Bumping package or WLP (Wafer Level Package) technology with mechanical/electrical isolation capability.

### BACKGROUND OF THE INVENTION

MEMS devices have long been attracting attentions due to a wide range of portable applications. For example, MEMS pressure sensor as altimeter has recently gained attraction due to the use of portable devices such as smart phones. MEMS pressure sensors can be made with resistor type or capacitive type. However, most of the MEMS pressure sensors were made with separate MEMS sensors and ASIC circuits with the final products assembled by wire bonding on top of a PCB substrate.

FIG. 1 shows a schematic view of a conventional structure of a MEMS pressure sensor with two-chip structure. As shown in FIG. 1, a two-chip structure of a MEMS pressure sensor includes a printed circuit board (PCB) 101 used as a base, a plurality of pads 102, a CMOS circuit 103, an epoxy 104 covering CMOS 103, a MEM circuit 105 further including a glass/silicon circuit 105a and a membrane 105b, a wall 106 for encompassing the entire structure, a plurality of wire bonds 107, a lid 108 and an air flow hole 109 for environmental air pressure. As shown in FIG. 1, a conventional two-chip MEMS pressure sensor requires wire bonding and complex packaging, such as, a wall, a lid and an air flow hole in the lid for environmental air pressure.

The problem with the two-chip solutions using wire bonding is that the wire is basically an inductive antenna and can pickup high frequency noise whose harmonics at low frequency band interferes with the signals in its frequency range. Another drawback of the above technology is the high cost due to packaging. Thus, it is imperative to devise a MEMS pressure sensor having high reliability and at the same time having low cost.

### SUMMARY OF THE INVENTION

The present invention has been made to overcome the above-mentioned drawbacks of conventional technologies for manufacturing MEMS pressure sensor. The primary object of the present invention is to provide an integrated MEMS device by using flip-chip wafer level package and ion implantation techniques for electrical/mechanical isolation.

Another object of the present invention is to provide a MEMS pressure sensor having high reliability and low manufacturing cost.

To achieve the above objects, the present invention provides a MEMS pressure sensor, with Flip Chip Bumping package or WLP (Wafer Level Package) capability. The integrated MEMS pressure sensor of the present invention combines CMOS ASIC and MEMS and uses flip chip package technology to fabricate. From the bottom up, the structure of an integrated MEMS pressure sensor of the present invention includes a CMOS substrate layer, an N+ implant doped silicon layer, a field oxide (FOX) layer, a plurality of implant doped silicon areas forming CMOS well, a two-tier polysilicon layer, further including an implant doped polysilicon layer and a non-doped polysilicon layer, a second non-doped polysilicon layer, a plurality of implant doped silicon areas forming CMOS source/drain, a gate poly layer made of polysilicon to form CMOS transistor gates, an oxide layer embedded with an interconnect contact layer, a plurality of metal layers interleaved with a plurality of via hole layers, wherein the number of metal layers and interleaving via hole layers can be adjusted according to ASIC design, a Nitride deposition layer, an under bump metal (UBM) layer and a plurality of solder spheres, said UBM layer and said solder spheres forming a flip chip bump layer. It is also worth noting that said N+ implant doped silicon layer and said implant doped/un-doped composition polysilicon layer form a sealed vacuum chamber.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional structure of a MEMS pressure sensor with two-chip structure;

FIG. 2 shows a cross-sectional view of an integrated MEMS capacitive pressure sensor with a single chip according to the present invention;

FIGS. 3A-3R show schematic views of an exemplary embodiment of a manufacturing process to fabricate the structure of integrated MEMS pressure sensor of the present invention; and

FIGS. 4A and 4B show a flowchart of an exemplary process for manufacturing the integrated MEMS pressure sensor of the present invention.

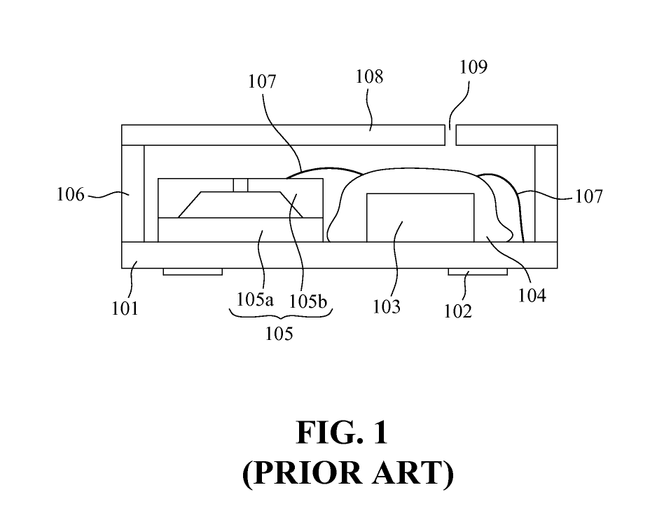

### DETAILED DESCRIPTION OF THE PREFERRED EMBODIMENTS

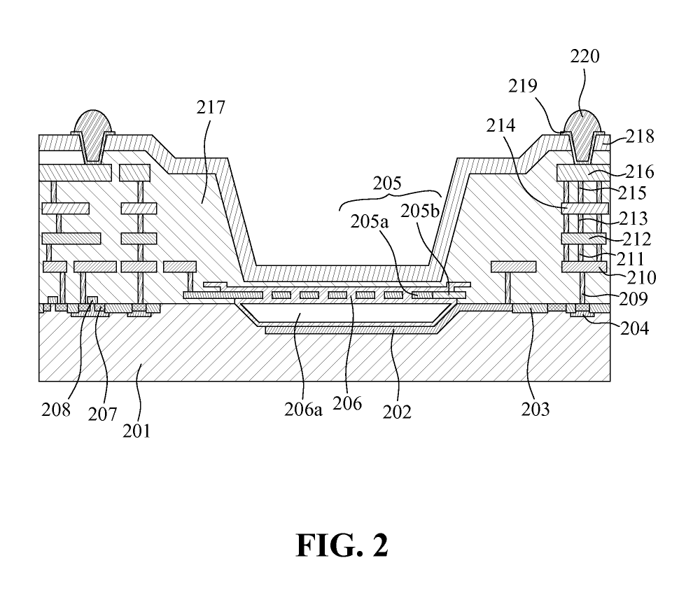

FIG. 2 shows a cross-sectional view of an exemplary embodiment of a MEMS device having a single chip structure fabricated to function as a MEMS pressure sensor according to the present invention. As shown in FIG. 2, the integrated MEMS pressure sensor of the present invention combines CMOS ASIC and MEMS and uses flip chip package technology to fabricate. From the bottom up, the structure of an integrated MEMS pressure sensor of the present invention includes a CMOS substrate layer 201, an N+ implant doped silicon layer 202, a field oxide (FOX) layer 203, a plurality of implant doped silicon areas 204 forming CMOS well, a two-tier polysilicon layer 205, further including an implant doped polysilicon layer 205a and a non-doped polysilicon layer 205b, a second non-doped polysilicon layer 206, a plurality of implant doped silicon areas 207 forming CMOS source/drain, a gate poly layer 208 made of polysilicon to form CMOS transistor gates, an oxide layer 217 embedded with an interconnect contact layer 209, a plurality of metal layers interleaved with a plurality of via hole layers, wherein this exemplary embodiments shows four metals and three via hole layers, including a first metal layer 210, a first via hole layer 211, a second metal layer 212, a second via hole layer 213, a third metal layer 214, a third via hole layer 215, and a fourth metal layer 216; a Nitride deposition layer 218, an under bump metal (UBM) layer 219 and a plurality of solder spheres 220, said UBM layer 219 and said solder spheres 220 forming a flip chip bump layer. It is also worth noting that N+ implant doped silicon layer 202 and second non-doped polysilicon layer 206 form a sealed vacuum chamber 206a.

For each layer, a plurality of preferred materials can be used. The following description is only for illustrative purpose, not restrictive. Equivalent materials can also be used to substitute the described materials. For example, CMOS substrate layer 201 is a P-doped CMOS substrate. Field oxide (FOX) layer 203 can be made of SiO₂ oxide, and a plurality of implant doped silicon areas 207 forms CMOS source/drain. Said CMOS wells, said CMOS transistor sources/drains and said CMOS gates (i.e., gate poly layer 208) form CMOS transistors. Interconnect contact layer 209, first via hole layer 211, second via hole layer 213, and third via hole layer 215 are preferably made of, such as, Ti/TiN/CVD-W. First metal layer 210, second metal layer 212, third metal layer 214, and fourth metal layer 216 are made of CMOS metals, such as, TiN/Cu/TiN or TiN/AlSi/TiN. It is worth noting that the number of said plurality of metals layers and via hole layers can be adjusted according to ASIC design requirements, and said plurality of metal layers with interleaved via hole layers collectively form a scribe seal. Nitride deposition layer 218 can be made of, such as, Si₃N₄ silicon Nitride. UBM layer 219 is preferably Al/NiV/Cu, solder spheres 220 can be made of, such as, Sn.

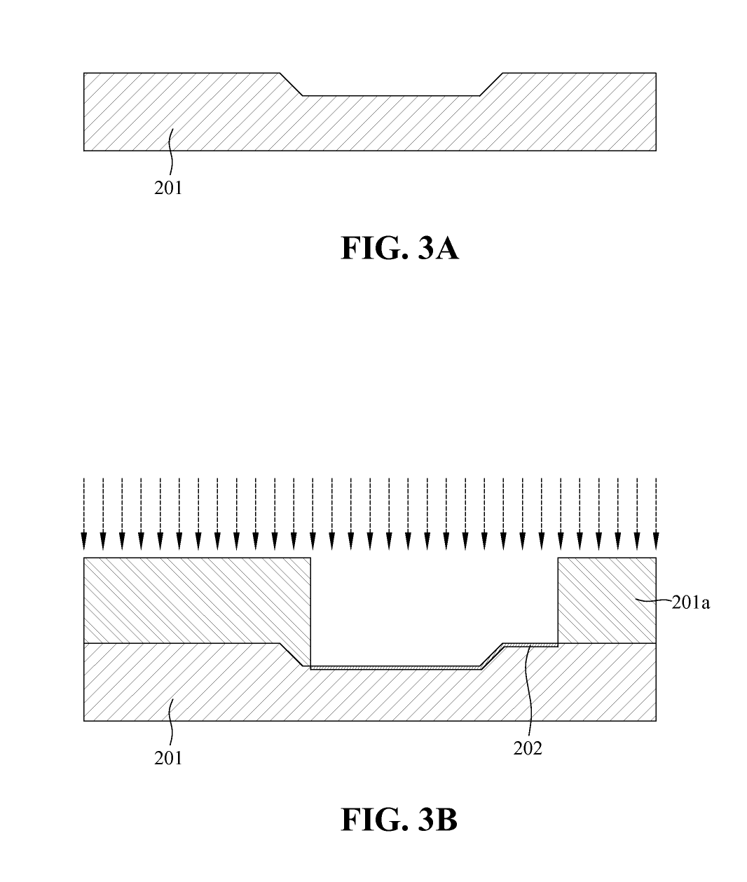

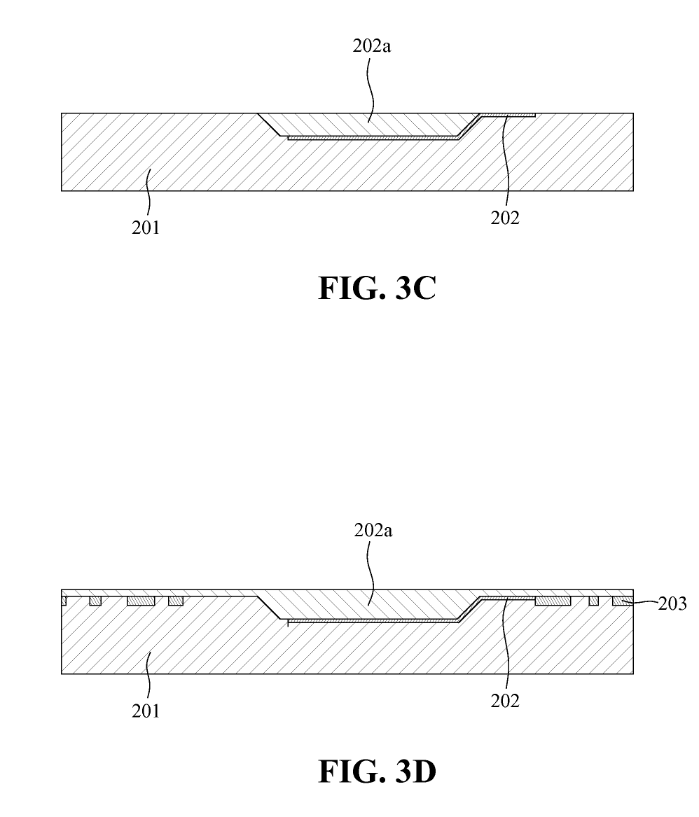

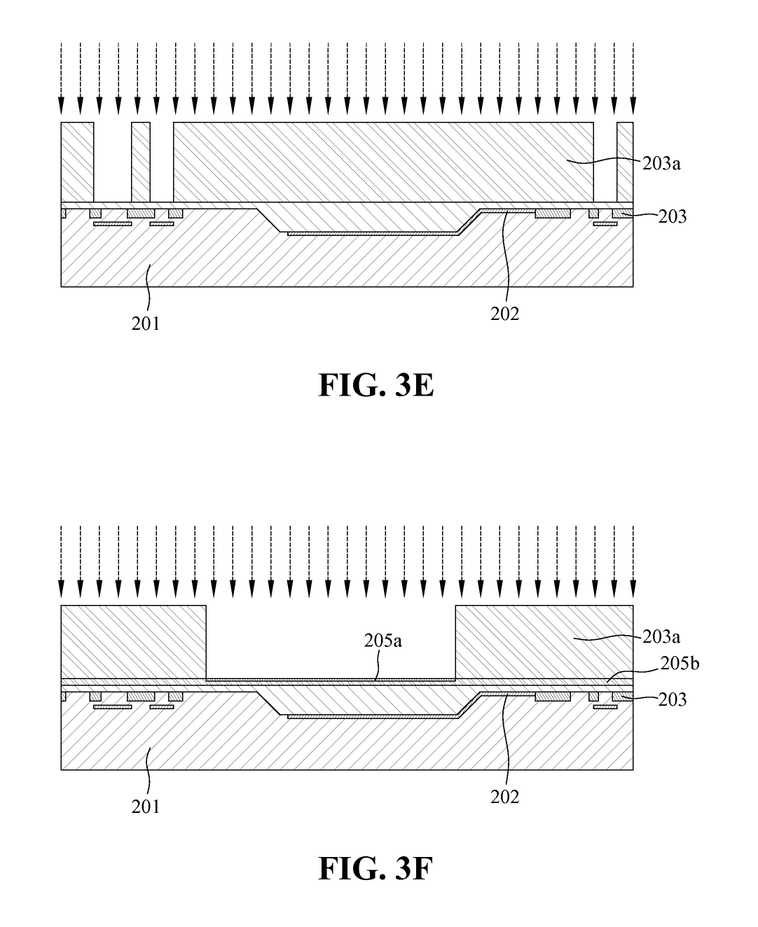

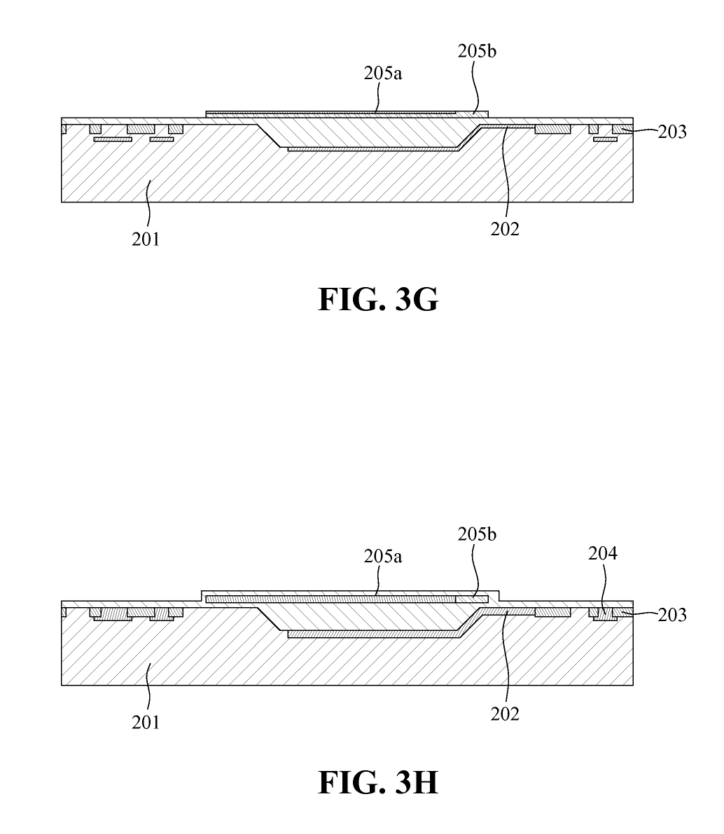

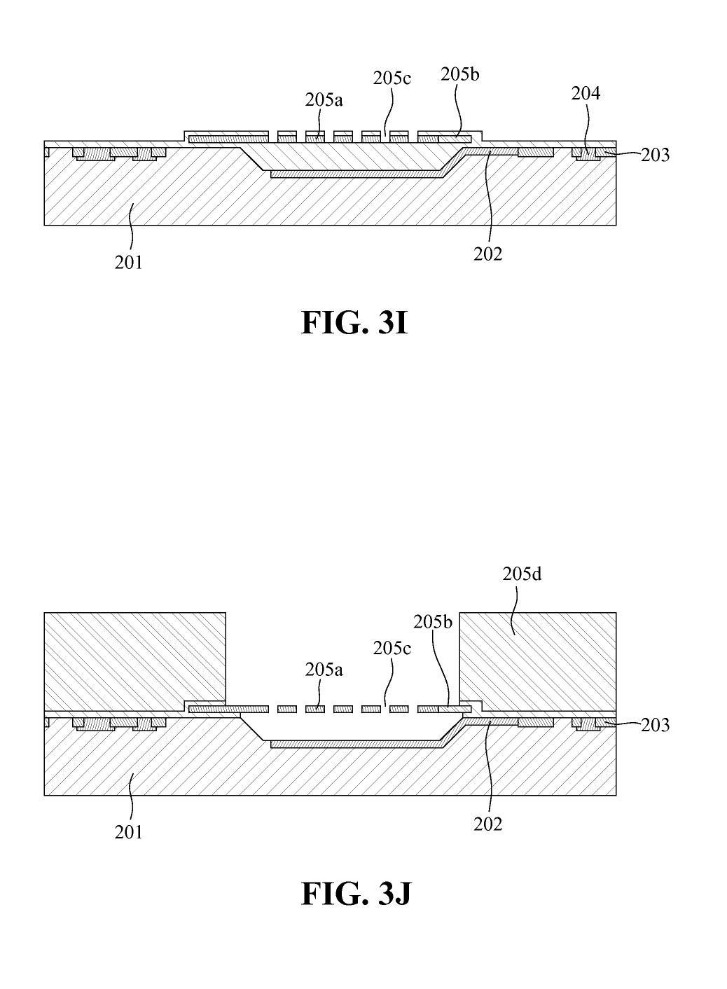

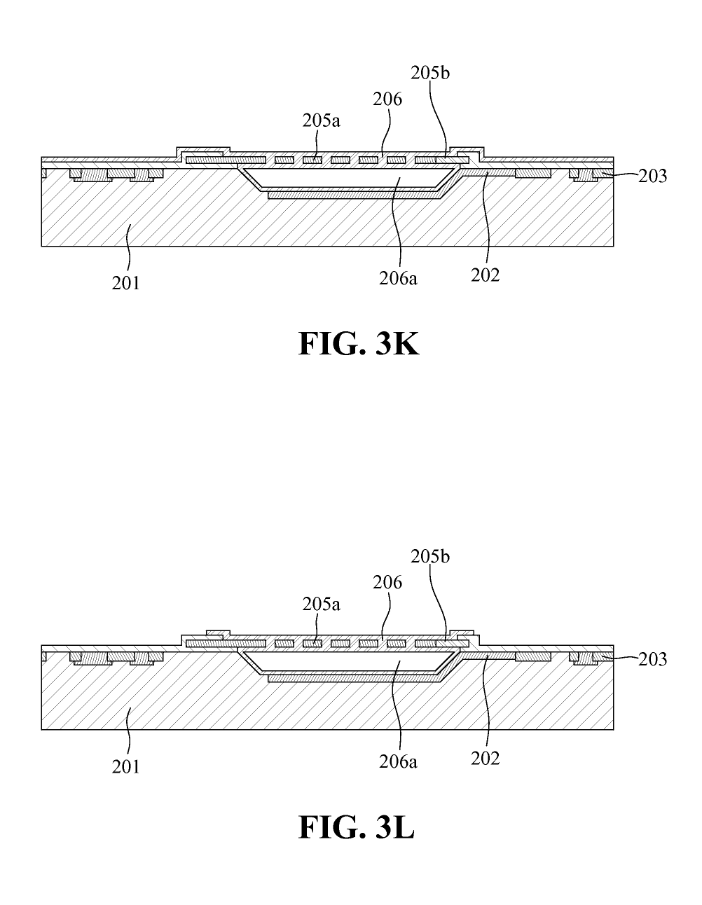

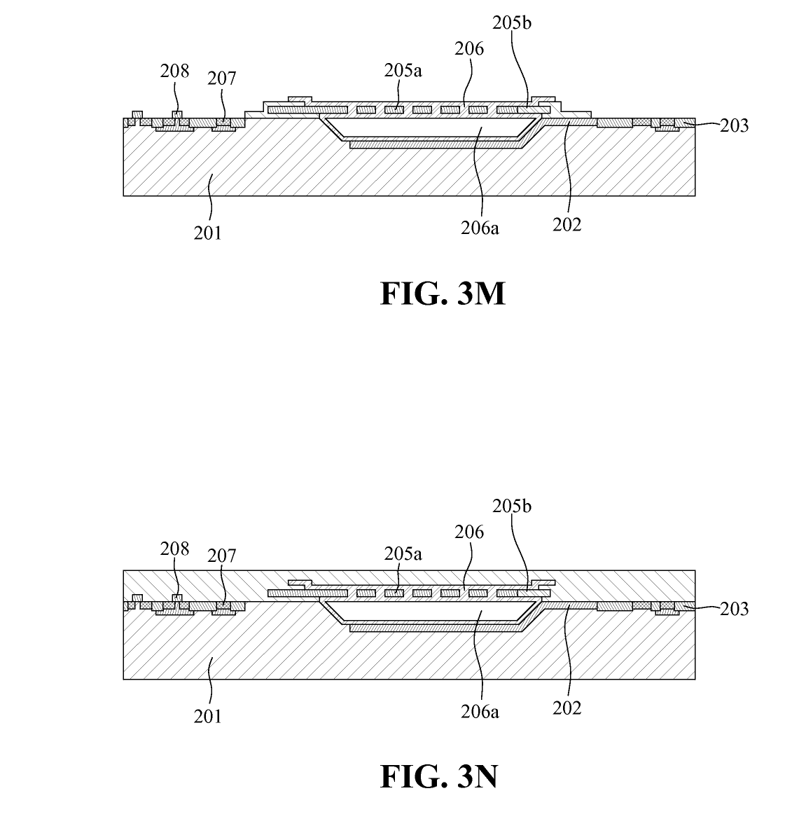

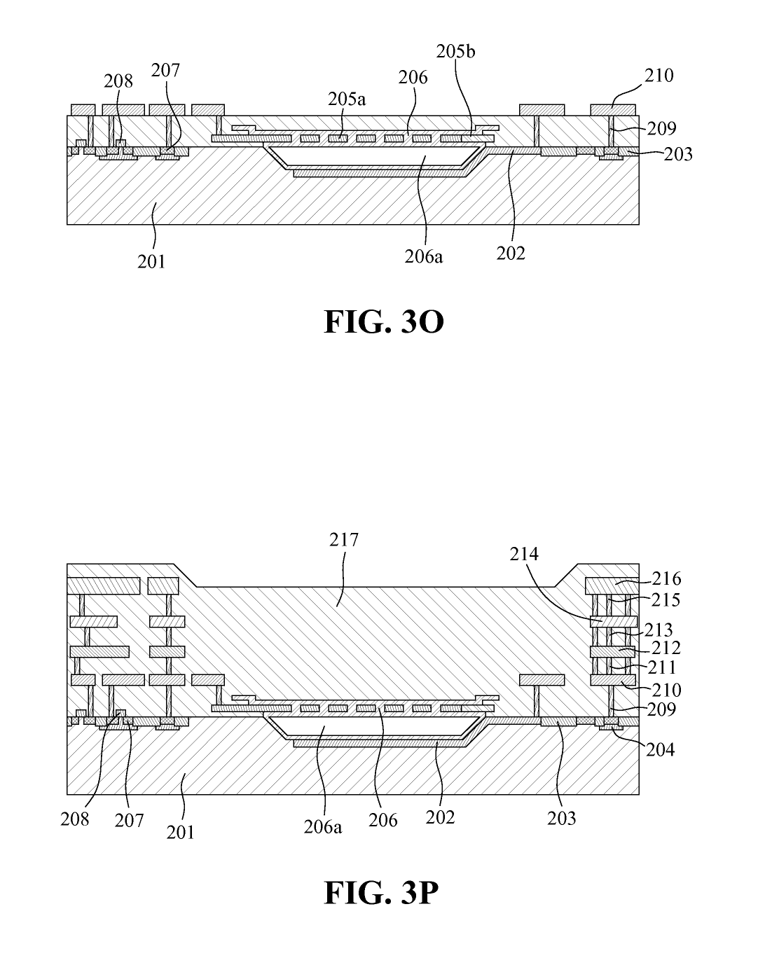

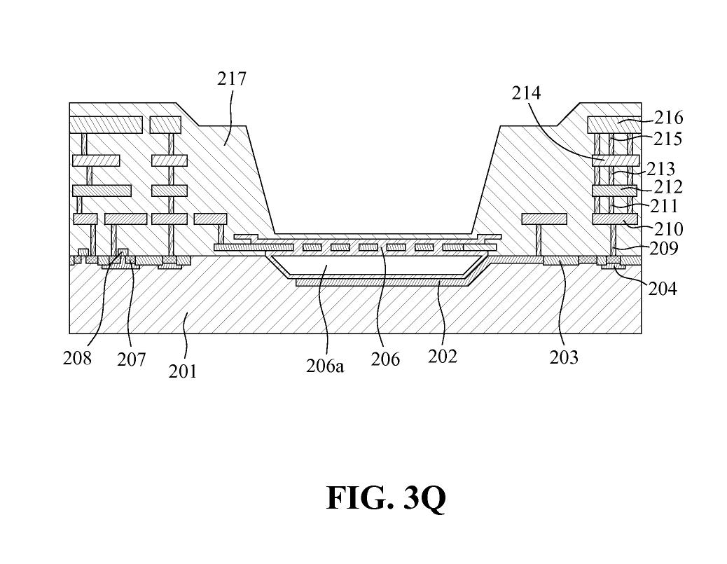

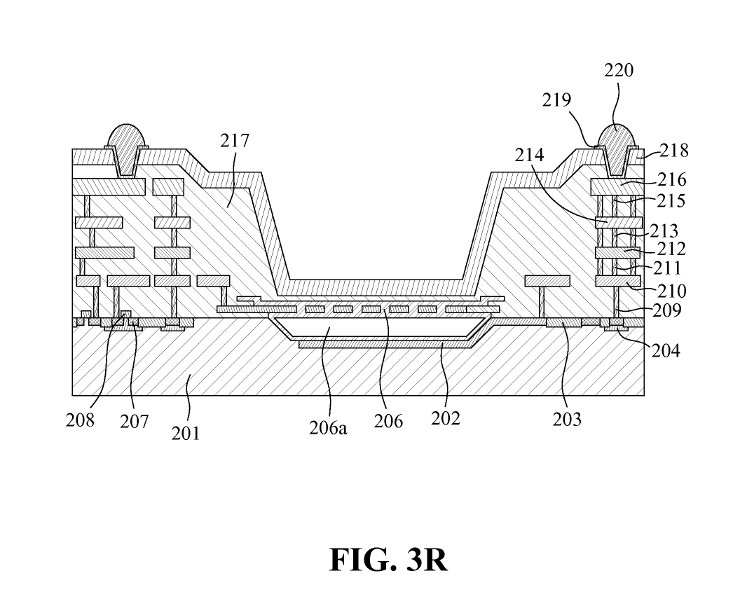

FIGS. 3A-3R shows schematic views of an embodiment of a manufacturing process able to fabricate the structure of integrated MEMS pressure sensor of the present invention. However, the process and constituting steps shown in FIGS. 3A-3R are only illustrative, instead of restrictive. Integrated MEMS pressure sensors manufactured in other processes are also within the scope of the structure of integrated MEMS pressure sensor of the present invention.

FIG. 3A shows a silicon substrate wafer 201 after wet silicon etches in MEMS area, which is the first step of the MEMS Deep Trench Oxide (DTO) process. The depth of silicon etch defines a gap between two capacitor plates of a MEMS capacitive pressure sensor device according to the present invention. The depth of silicon etch is preferably around 1-3 um. FIG. 3B shows a schematic view that a photo resist pattern 201a is then used for a selective N+ ion implantation doping to form an N+ implant doped silicon layer 202, and thus form N+P junction with P− substrate 201. N+ implant doped silicon layer 202 serves as a bottom plate electrode of MEMS device. FIG. 3C shows that N+ implant doped silicon layer 202 is offset from recessed silicon area 202a. The purpose of the offset is to isolate mechanical MEMS function and electrical MEMS function such that the electrical function is optimized without limitation by the mechanical purpose of the MEMS device, whose objective will become clearer in a later description. As shown in FIG. 3C, an LPCVD thick oxide deposition of around 1-3 um and then oxide Chemical Mechanical Polish (CMP) process are performed. At the end of FIG. 3C, the MEMS DTO process is completed. The N+ ion can be Arsenic or Phosphorus or a combination of both.

In FIG. 3D, the wafer is then going through CMOS Shallow Trench Isolation (STI) process to form Field Oxide (FOX) layer 203 in the CMOS area. In the present invention, the aforementioned MEMS DTO process is to form deep trench oxide in MEMS area and the STI process is to form shallow trench oxide isolation in CMOS area. In FIG. 3E, a CMOS well photo resist pattern 203a with high energy ion implantation is performed. FIG. 3F shows a view after removing photo resist pattern 203a, and then non-doped polysilicon layer 205b is deposited for forming MEMS membrane, preferable 0.3-0.6 um, followed by selective ion implantation (implant doped polysilicon layer 205a) to dope the membrane for mechanical/electrical isolation. Implant doped polysilicon layer 205a and non-doped polysilicon layer 205b collectively form two-tier polysilicon layer 205. FIG. 3G shows a view after the membrane is etched with a photo resist pattern followed by photo resist removal. In FIG. 3H, a CMOS well high temperature drive-in process, usually 1000-1100° C. for 3-4 hours, is performed to form CMOS wells 204. Since the polysilicon membrane is deposited on top of DTO and ion implanted with dopants prior to the CMOS well high temperature drive-in, the high temperature of CMOS well drive-in process will anneal the implant doped polysilicon membrane. Because the high temperature anneal also significantly reduces the polysilicon mechanical stress, the present invention uses the CMOS well high temperature drive-in process to obtain low stress membranes, a preferred polysilicon mechanical property for MEMS applications. The same high temperature also anneals the implanted N+ ion in FIG. 3B to form N+ junction with P− substrate with N+ implant doped silicon layer 202 serving as the capacitor bottom plate. The DTO process has thus served three key purposes: (a) defining the distance between capacitor plates and thus capacitance, (b) allowing CMOS well high temperature drive-in to perform membrane stress relief by holding implanted membrane on top of surface, and (c) forming a sealed chamber for membrane movements, which will become clear later in the description.

As shown in aforementioned FIG. 3F, the ion implantation on the membrane is offset from the DTO area. The purpose of the offset ion implantation is to reduce the parasitic capacitance of the capacitor plates. The un-doped areas of the capacitor plates are non-conductive and having properties of a dielectric. The selective ion implantation doping adjusts the distance of the conductive area of the top and bottom capacitor plates in horizontal direction, so that the parasitic capacitance is minimized while the effective capacitance of the conductive plates is maximized. With proper layout of the implantation layer to dope the electrodes of the MEMS capacitor plates, the parasitic coupling capacitance between the two electrodes can be significantly reduced to close to zero, and active moving membrane capacitance becomes a dominant capacitance of the entire MEMS capacitor. Thus, by performing the ion implantation on the membrane, the mechanical purpose of holding the membrane at the edge is achieved as shown in FIG. 3H. It is worth noting that the N+ implant doped polysilicon is used as an example for the membrane, however, P+ Boron doped poly silicon can be used as well when deems necessary for the mechanical property of the polysilicon membrane. As shown in FIG. 3I, a polysilicon pattern and etch step is then performed to form oxide release openings 205c in the membrane area. An oxide release photo resist pattern 205d and an oxide release step are then performed, as shown in FIG. 3J. After photo resist 205d is removed, the wafer then goes through isotropic conformal LPCVD non-doped polysilicon deposition to form an un-doped polysilicon layer. Due to the isotropic nature of the deposition, the bottom and the side wall of the empty chamber is filled with non-doped LPCVD polysilicon (layer 206) until the holes that the poly silicon passing through are fully filled and sealed, as shown in FIG. 3K. The openings are sealed when the hole diameter D is equal to twice of the deposited poly silicon thickness T, D=2T. FIG. 3L shows a view of the structure after sealing and remaining oxides on the CMOS area then patterned and etched away. The parasitic capacitance between the two capacitor plates forming the capacitive pressure sensors are significantly reduced by offsetting the implant region in the bottom plate (N+ implant doped silicon layer 202) and the top plate (layer 205). The overlap region of layers 202 and 205 are the active capacitor plate. Since the overlap regions at the mechanical anchor region is not doped and thus are not conductive, the parasitic capacitance is minimized. FIG. 3M shows a view of a plurality of implant doped silicon areas 207 forming CMOS source/drain, followed by a high quality gate oxide thermally grown, and then with polysilicon deposition to form a gate poly layer 208. Gate poly layer 208 is then patterned and etched to form a plurality of CMOS transistor gates, followed by transistor source/drain implant and anneal to form CMOS transistors, as shown in FIG. 3N. The above CMOS transistor source/drain anneal process step also anneals the second non-doped polysilicon layer (layer 206) for mechanical stress relief. The resulting wafer is then deposited with CMOS Inter-Level-Oxide (ILD) and CMOS ILD oxide planarization is performed before the formation of contact layer 209 and first metal layer 210.

FIG. 3O shows both top plate doped polysilicon (layer 205a) and bottom plate N+ electrodes (layer 202) are contacted through interconnect contact layer 209 with first metal layer 210. In FIG. 3P, the wafer is then going through CMOS interconnect process from second metal layer 212 to fourth metal layer 216 with CMOS Multi-Level-Oxide (MLD), i.e., via hole layers 211, 213 and 215, in between metal layers. The differential capacitance between the two capacitor plates (layers 202 and 205a) is fed to the ASIC input terminal through the first metal layer (layer 210) to fourth metal layer (layer 216) connecting schemes through interleaving via hole layers. When the external pressure increases, the gap between the capacitor electrodes becomes smaller, and thus the capacitance increases. The incremental capacitance change will be amplified by the on-chip ASIC circuits, and thus the pressure change is converted to electrical signals which are further processed to display as absolute pressure or height above the sea level, functions and purposes of a typical pressure sensor. At the end of this step, metal layers and interleaving via hole layers are embedded inside an oxide layer 217.

In FIG. 3Q, the MEMS large area oxide is patterned and etched, with etch stops at the polysilicon top layer 206. At this stage, a thin oxide layer may be optionally deposited before Protective Overcoat (PO) silicon nitride deposition to be compatible with a CMOS process. In FIG. 3R, PO silicon nitride layer 218 is then deposited followed with Flip chip bumping process with Under Bump Metal (UMB) layer 219 and solder spheres 220, a complete CMOS circuit with a wafer level package (WLP) capability. An integrated MEMS capacitive pressure sensor with flip chip bumping and WLP capability and selective ion implantation doping for mechanical/electrical isolation of MEMS devices and DTO in a CMOS process are then formed and completed.

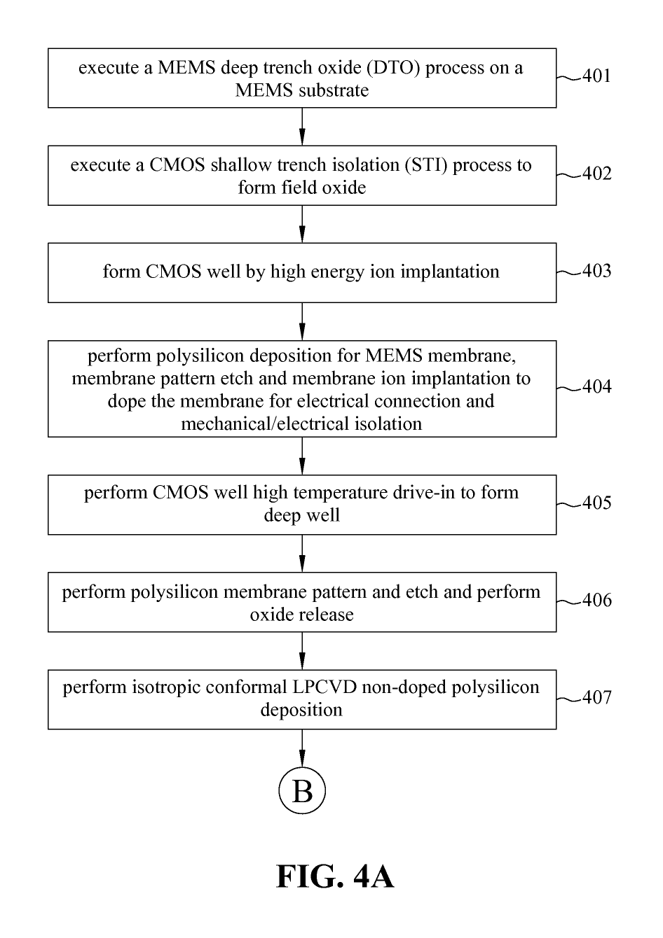

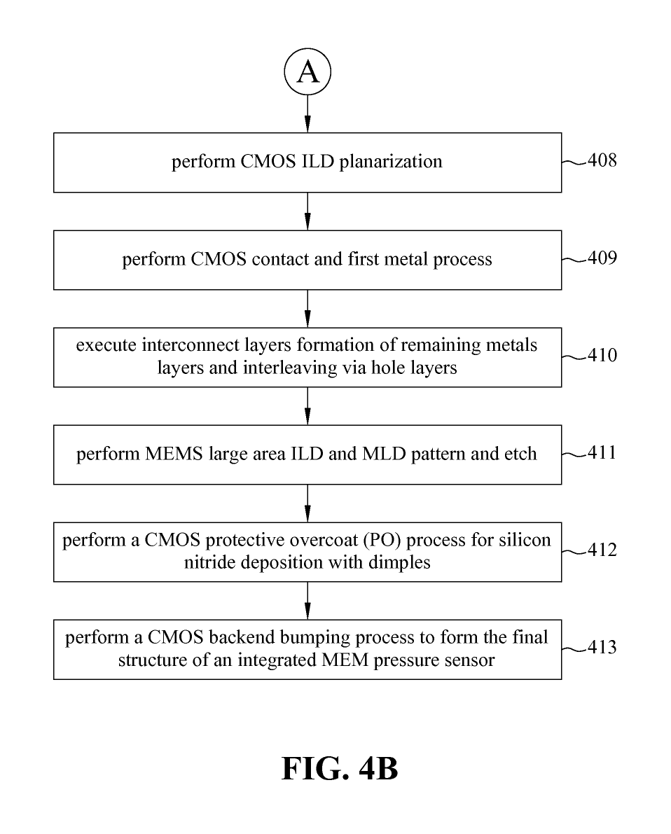

FIGS. 4A and 4B show a flowchart of an exemplary process for manufacturing the integrated MEMS pressure sensor of the present invention. As shown in FIG. 4A, step 401 is to execute a MEMS deep trench oxide (DTO) process on a MEMS substrate, further including the steps of: silicon recessed wet etch; photo resist pattern for selective N+ ion implantation to form junction with P− substrate for bottom plate electrode and mechanical/electrical isolation; and LPCVD oxide deposition and Chemical Mechanical Polish (CMP) to fill the MEMS silicon recessed area. Step 402 is to execute a CMOS shallow trench isolation (STI) process to form field oxide. Step 403 is to form CMOS well by high energy ion implantation. Step 404 is to perform polysilicon deposition for MEMS membrane, membrane pattern etch and membrane ion implantation to dope the membrane for electrical connection and mechanical/electrical isolation. Step 405 is to perform CMOS well high temperature drive-in to form deep well. It is worth noting that the high temperature will also anneal the implant doped polysilicon membrane for stress relief; hence, a low-stress membrane can be obtained. Step 406 is to perform polysilicon membrane pattern and etch and perform oxide release. Step 407 is to perform isotropic conformal LPCVD non-doped polysilicon deposition. As shown in FIG. 4B, following step 407 in FIG. 4A, step 408 is to perform CMOS ILD planarization. Step 409 is to perform CMOS contact and first metal process. Step 410 is to execute interconnect layers formation of remaining metals layers and interleaving via hole layers, such as, second metal layer, third metal layer and fourth metal layer and via hole layers of FIG. 2. Step 411 is to perform MEMS large area ILD and MLD pattern and etch. Step 412 is to perform a CMOS protective overcoat (PO) process for silicon nitride deposition with dimples. Step 413 is to perform a CMOS backend bumping process to form the final structure of an integrated MEM pressure sensor.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An integrated MEMS pressure sensor with mechanical electrical isolation, comprising, from bottom up:
a CMOS substrate layer;
an N+ implant doped silicon layer;
a field oxide (FOX) layer;
a plurality of implant doped silicon areas forming CMOS wells,
a second ion implant doped silicon layer, forming CMOS source/drain;
a two-tier polysilicon layer, further including an implant doped polysilicon layer and a non-doped polysilicon layer;
an implant doped/un-doped composition polysilicon layer, forming a sealed vacuum chamber with said N+ implant doped silicon layer;
a gate poly layer, made of polysilicon to form CMOS transistor gates, said CMOS wells, said CMOS transistor sources/drains and said CMOS gates forming CMOS transistors;
an oxide layer, embedded with an interconnect contact layer, a plurality of metal layers interleaved with a plurality of via hole layers, said interconnect contact layer providing contacts to said CMOS transistors;
a Nitride deposition layer;
an under bump metal (UBM) layer; and
a plurality of solder spheres, said UBM layer and said solder spheres forming a flip chip bump layer;
wherein said CMOS substrate layer having a recessed silicon area, said an N+ implant doped silicon layer serving as a bottom plate of a capacitor and said implant doped/un-doped composition polysilicon layer serving as a top plate of said capacitor.

2. The integrated MEMS pressure sensor as claimed in claim 1, wherein number of said plurality of metal layers and number of said interleaving via hole layers can be adjusted.

3. The integrated MEMS pressure sensor as claimed in claim 1, wherein said sealed vacuum chamber forms a gap for said capacitor plates and determines capacitance of said capacitor.

4. The integrated MEMS pressure sensor as claimed in claim 3, wherein depth of said recessed silicon area on said CMOS substrate determines said gap of said sealed vacuum chamber.

5. The integrated MEMS pressure sensor as claimed in claim 1, wherein said capacitor plates comprise ion implantation for electrical conductivity.

6. The integrated MEMS pressure sensor as claimed in claim 1, wherein said implant doped/un-doped composition polysilicon layer is a composition polysilicon layer comprises both implant doped and un-doped layers formed by selective ion implantation for electrical functions.

7. The integrated MEMS pressure sensor as claimed in claim 1, wherein an isolated N+P junction is formed with said recessed silicon area of said CMOS substrate by selective ion implantation.

8. The integrated MEMS pressure sensor as claimed in claim 1, wherein oxide area on top of MEMS is etched to reduce MEMS film thickness and thus increase sensitivity.

9. The integrated MEMS pressure sensor as claimed in claim 1, wherein mechanical/electrical isolation of a MEMS pressure sensor is achieved by MEMS layers with selective ion implantation.

10. A manufacturing process for forming an integrated MEMS pressure sensor, comprising the steps of:
executing a MEMS deep trench oxide (DTO) process on a MEMS substrate;
executing a CMOS shallow trench isolation (STI) process to form field oxide;
forming CMOS well by high energy ion implantation;
performing polysilicon deposition for MEMS membrane, membrane pattern etch and membrane ion implantation to dope the membrane for electrical connection and mechanical/electrical isolation;
performing CMOS well high temperature drive-in to form deep well;
performing polysilicon membrane pattern and etch and perform oxide release;
performing isotropic conformal LPCVD non-doped polysilicon deposition;
performing CMOS inter-level-oxide (ILD) planarization;
performing CMOS contact and first metal process;
executing interconnect layers formation of remaining metals layers and interleaving via hole layers;
performing MEMS large area ILD and multi-level-oxide (MLD) pattern and etch;
performing a CMOS protective overcoat (PO) process for silicon nitride deposition with dimples; and
performing a CMOS backend bumping process to form final structure of said integrated MEM pressure sensor.

11. The manufacturing process as claimed in claim 10, wherein said DTO process further comprises the steps of:
performing silicon recessed wet etch;
photo resist pattern for selective N+ ion implantation to form junction with P− substrate for bottom plate electrode and mechanical/electrical isolation; and
LPCVD oxide deposition and Chemical Mechanical Polish (CMP) to fill the MEMS silicon recessed area.

12. The manufacturing process as claimed in claim 10, wherein a Flip Chip Bumping package or WLP (Wafer Level Package) is adopted.

13. The manufacturing process as claimed in claim 10, wherein said CMOS well high temperature drive-in also anneals implant doped polysilicon membrane to obtain a low-stress membrane.
